(19) United States
(12) Patent Application Publication
(10) Pub. No.: US 2008/0165521 A1
(43) Pub. Date: Jul. 10, 2008

(54) THREE-DIMENSIONAL ARCHITECTURE FOR SELF-CHECKING AND SELF-REPAIRING INTEGRATED CIRCUITS

(76) Inventors: KERRY BERNSTEIN, Underhill, VT (US); Paul William Coteus, Yorktown, NY (US); Ibrahim (Abe) M. Elfadel, Cortlandt Manor, NY (US); Philip George Emma, Danbury, CT (US); Kathryn W. Guarini, Yorktown Heights, NY (US); Thomas Fleischman, Poughkeepsie, NY (US); Allan Mark Hartstein, Chappaqua, NY (US); Ruchir Puri, Baldwin Place, NY (US); Mark B. Ritter, Sherman, CT (US); Jeannine Madelyn Trewhella, Peekskill, NY (US); Albert M. Young, Fishkill, NY (US)

Correspondence Address: KEUSEY, TUTUNJIAN & BITETTO, P.C., 20 CROSSWAYS PARK NORTH, SUITE 210, WOODBURY, NY, 11797, US

(21) Appl. No.: 11/621,188

(22) Filed: Jan. 9, 2007

(51) Int. Cl. H05K 7/00; H01L 21/50

(52) U.S. Cl. 361/820; 438/109; 257/E21.499

(57) ABSTRACT

A three-dimensional architecture chip includes a base chip including a unit integrated thereon and configured to perform electrical signal operations. An active layer is separately fabricated from the base layer. The active layer includes a component to service the unit of the base chip. The active layer is bonded to the base chip such that the component is aligned in vertical proximity of the unit. An electrical connection connects the unit to the component through vertical layers of at least one of the base chip and the active layer.

### GOVERNMENT RIGHTS

This invention was made with Government support under Contract No.: N66001-04-C-8032 awarded by the Defense Advanced Research Projects Agency (DARPA). The Government has certain rights in this invention.

### BACKGROUND

1. Technical Field

The present invention relates to circuit architectures and more particularly to circuit designs employing semiconductor stacks having power circuits, self-repairing circuits, self-checking circuits or other integrated circuits advantageously positioned in the stack.

2. Description of the Related Art

Reliability, availability and serviceability (RAS) of complex integrated circuits, such as high performance microprocessors, require that fault detection and repair actions happen immediately after fault occurrence. Otherwise, several clock cycles are wasted during which erroneous instruction and data information are spread throughout the system. This would make recovery and state rollback to a last correct state very difficult given the exponential growth of a fault tree.

One way to have an early detection of fault occurrence is to place function checkers and fault detection circuitry as close as possible to the hardware where checking is needed. This is in contrast to relegating the monitoring and recovery capabilities to the system or firmware levels. The problem with bringing fault-detection, repair, and recovery functions to the hardware level is the negative impact that implementing such circuitry has on chip area, wireability, and performance of the overall chip.

### SUMMARY

A three-dimensional architecture chip includes a base chip including a unit integrated thereon and configured to perform electrical signal operations. An active layer is separately fabricated from the base layer. The active layer includes a component to service the unit of the base chip. The active layer is bonded to the base chip such that the component is aligned in vertical proximity of the unit. An electrical connection connects the unit to the component through vertical layers of at least one of the base chip and the active layer.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a cross-sectional view showing a first integrated circuit chip formed to a first contact layer and a handle wafer being applied;

FIG. 2 is a cross-sectional view showing the first integrated circuit chip with a component being aligned with a unit in a second integrated circuit chip and the two integrated circuits being bonded together;

FIG. 3 is a cross-sectional view showing the first and second integrated circuit chips bonded and a electrical connection being formed (e.g., using a damascene process) to electrically connect the component of the first integrated circuit chip to the unit of the second integrated circuit chip;

FIG. 4 is a schematic cross-sectional view showing a stack of chips having spare or redundant components thereon for serving a processing core of a base chip;

FIG. 5 is a schematic cross-sectional view showing a stack of chips having a redundant processing core for error detection;

FIG. 6 is a schematic cross-sectional view showing a stack of chips having a fault detection circuit split between two integrated circuit chips in the stack;

FIG. 7 is a schematic cross-sectional view showing a stack of chips having mirrored logic components in one chip to simulate sensitive logic in a base chip to detect errors in the sensitive logic;

FIG. 8 is a schematic cross-sectional view showing a shadow unit which mimics operation of a unit in a base chip to detect errors; and

FIG. 9 is a schematic cross-sectional view showing a stack of chips having memory storage vertically proximate to a unit that uses the memory storage.

### DETAILED DESCRIPTION OF PREFERRED EMBODIMENTS

Embodiments in accordance with present principles preferably employ the manufacturing of three-dimensional chips by bonding several active layers in one stack along with interconnect level connection between each portion of the stack. For present purposes, a chip may be defined as an integrated circuit including one more passive or active elements. A stack includes two or more chips operatively coupled to each other to perform an operation. A stack may be referred to as having a three-dimensional architecture or as a three-dimensional chip, since the stack employs not only a layout area but a stack height. Separately fabricated refers two chips fabricated separately in different processes and perhaps remote locations.

In accordance with present principles, fabrication and manufacturing methods are employed to take advantage of the stacking capabilities in designing fault-detection, repair, and recovery circuits that run concurrently with monitored hardware. Design and architectures implemented in three-dimensional semiconductor stacks provide self-checking integrated circuits, self-repairing integrated circuits, power management integrated circuits, redundant components, etc. that are closer in proximity to hardware needing these services or functions. Vertical proximity will be referred to herein to describe a placement area for a component on an active layer above or below a unit on a different chip that it services. The placement area is such that improved performance is achieved by such placement.

Embodiments of the present invention can take the form of a hardware embodiment that may include any types of integrated circuit or combinations thereof. Integrated circuits may include, for example, electronic, magnetic, optical, electromagnetic, infrared, or other semiconductor devices or components.

Integrated circuits or chips as provided herein may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., Graphic Data System II (GDSII)) for the fabrication of photolithographic masks, which typically include multiple copies of the chip design in question that are to be formed on a wafer. The photolithographic masks are utilized to define areas of the wafer (and/or the layers thereon) to be etched or otherwise processed.

The method as described herein is preferably employed in the fabrication of integrated circuit chip stacks. The resulting integrated circuit chip stacks can be distributed by the fabricator in multiple packaged forms. In one example, the stack is mounted in a chip package (such as a plastic carrier, with leads that are affixed to a motherboard or other higher level carrier) or in a multichip package (such as a ceramic carrier that has either or both surface interconnections or buried interconnections). In any case the chip stack may be integrated with other chips, stacks, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

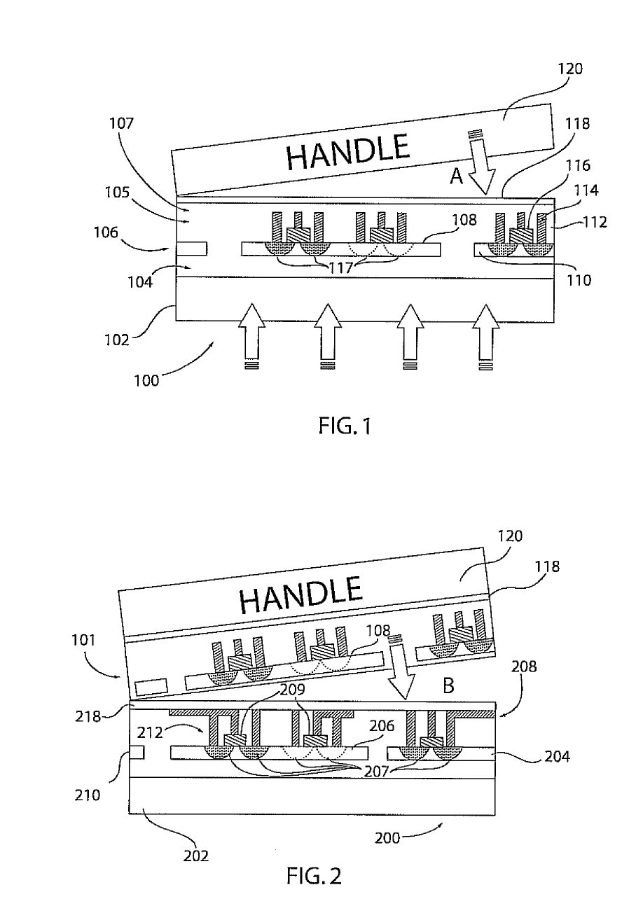

Referring now to the drawings in which like numerals represent the same or similar elements and initially to FIG. 1, a semiconductor fabrication process provides an integrated circuit chip 100 processed up to a first contact level (V1) 112. Processing includes forming a plurality of layers on a substrate 102. Substrate 102 may include a semiconductor material or any other material compatible with semiconductor processing. Layer 104 may include a dielectric material such as silicon dioxide or the like. In the illustrative embodiment shown, a silicon-on-insulator substrate 108 may be bonded or otherwise attached to layer 104. Alternately, layer 106 may be formed on layer 104 and processed as is known in the art.

Layer 106 or substrates 108 and 110 are processed to form active devices and/or passive devices. Active devices may include transistors, diodes, or entire circuits such as but not limited to self-repair circuits, self-checks circuits, monitoring circuits, etc. Passive devices may include resistors, capacitors, inductors, etc. After processing of layer 106 is completed a dielectric layer 105 may be formed and patterned to provide contact layer V1 112 with contacts 114 to gate structures 116 and diffusion regions 117. Layer 112 is buried by further depositing dielectric material 107.

An adhesive layer 118 is formed on layer 107 to provide a bond to a handle wafer 120. Handle wafer 120 is provided to protect integrated circuit chip 100 during transport and/or further processing, and provide a gripping position. Substrate 102 can now be removed to provide an active device layer 101 (FIG. 2) connected to the handle wafer 120. Active device layer 101 is configured to provide one or more functions, which are employed to enhance performance of another integrated circuit when formed in a stack. In one example, active device layer 101 includes one or more of a checker, monitor, fault detector, power or temperature monitor or other device positionally corresponding to a device or feature on another active device layer or chip such that when assembly the devices are in proximity with each other. The proximity can be employed to a performance advantage. This proximity should be determined at the design stage to ensure that the devices line up in an advantageous way.

Advantageously, active layer or layers 101 provide additional area for placing checkers, monitors, fault detectors right above or below important circuits or units of a processor, memory chip or other integrated circuit device.

Referring to FIG. 2, a second integrated circuit chip 200 includes a substrate 202 (e.g., a semiconductor substrate) having processed layers formed through a first level metal layer m1 208. Contact layer 212 includes contacts to gates 209 and diffusion regions 207 as is known in the art. An interlevel dielectric layer (ILD) 218 is formed over M1 layer 208 and planarized.

Chip 200 may be any type of device, e.g., a processor, a memory chip, a combination thereof, etc. Chip 200 includes devices or circuits that may need to be monitored, checked, corrected, etc. Active device layer 101 includes circuits e.g., circuit 108, which provides one or more functions to a circuit 206 which will be in close vertical proximity to circuit 108 once assembled. In this process, the active device layer 101 is aligned with chip 200 and bonded to chip 200. Alignment is preferably within about a 0.5-1.5 micron tolerance; however this depends on the application and the technology. Alignment can be carried out using known techniques. Active device layer 101 is bonded to chip 200, by e.g., fusion bonding or polymer bonding. The area of placement of a component on active device layer 101 is aligned to the unit of the base chip 200 that the component will service. The proximity to which the component is placed with reference to the unit will depend on many factors, such as, performance improvements needed, heat dissipation considerations, processing considerations, etc. Other circuits 204 may also have components arranged to be near or above/below circuits of active layer 101 by adjusting other aspects of the design.

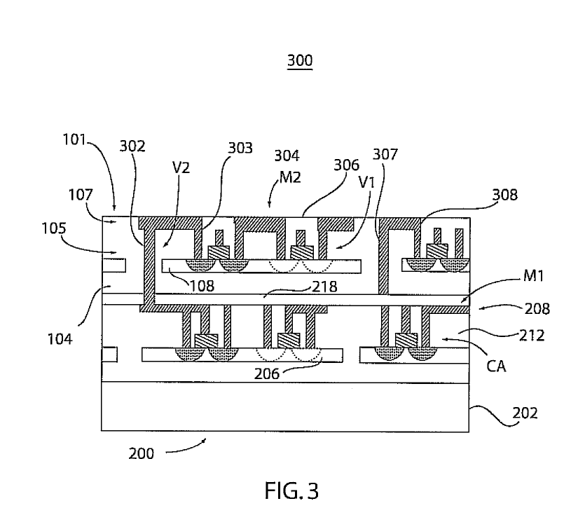

Referring to FIG. 3, handle wafer 120 and adhesive 118 are removed. Etching is performed to form openings through dielectric material, e.g., layers 104, 105, 107, 218, etc. for forming vias (V2) and/or metal lines (M2) Vias 302, 303, 307 are formed in via layer V2 by depositing a conductive material in the openings. In this example, via 302 extends into chip 200 and contacts M1. Via 307 reaches ILD 218.

Metal lines M2 308 may be formed simultaneously with vias V2 in a dual damascene process, or metal lines M2 may be formed in a separate deposition process (e.g., single damascene process). Metal lines M2 308 make connection between devices in active device layer 101 and chip 200. A top surface 306 is planarized, e.g. by a chemical mechanical polish process. Top surface 306 may now be further processed by additional deposition processes or additional active layer devices may be added. The additional active layer devices may provide support functions for active layer device 101, chip 200 or devices or layers formed above active layer device.

In the illustrative embodiment depicted in FIG. 3, circuits 206 are brought into close vertical proximity. If for example, circuit 206 were a processing core and circuit 108 were a fault detection circuit, given the short vertical connections, fault detection may be provided within one to two clock cycles. This will also help avoid any congestion and wireability problems.

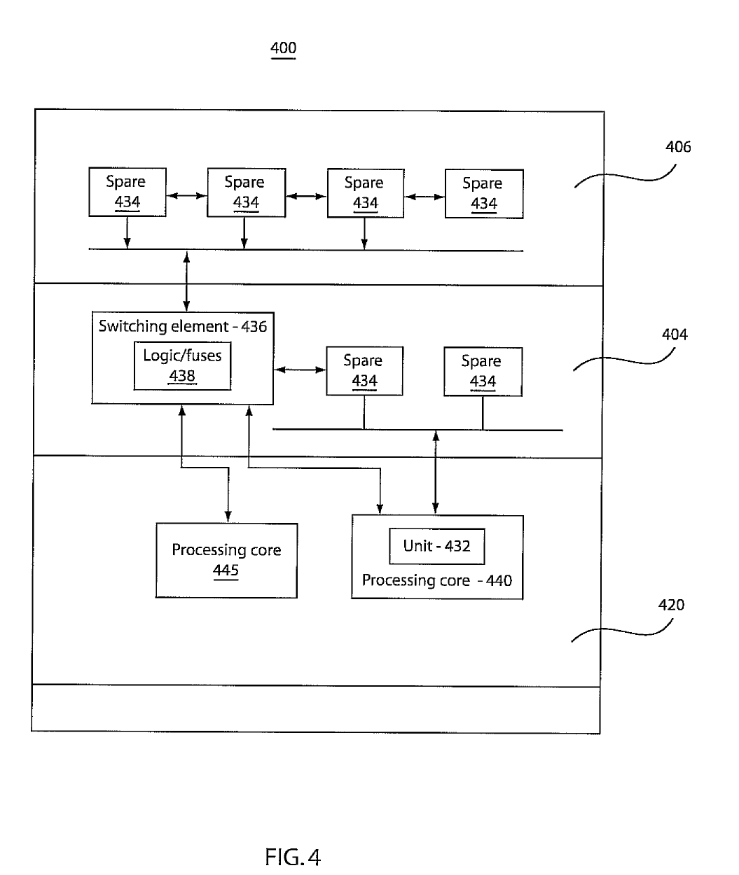

Referring to FIG. 4, a schematic diagram shows an illustrative cross-section of a three-dimensional device stack 400 having a plurality of active layers 404 and 406 added to a base chip 420. Active layers 404 and 406 may be applied after processing and alignment as similarly described for active layer 101 in FIG. 3. Present principles are illustratively depicted in FIG. 4, and thus, actual circuits and components may take on a plurality of different sizes, shapes, orientations and configurations with the teachings presented herein.

Active layers 404 and 406 provide additional area for placing checkers, monitors, fault detectors, power management devices, spare or redundant circuits directly above or below important circuits or units of a processor, memory chip or other integrated circuit device. In one embodiment, active layers 404 and 406 can function as a repository of “spare parts” 434 for one or more units 432 in a processor 440. A switching element 436 provided on the additional active layer 404 may include control logic or fuses 438, which may be employed to bring up a spare part 434 and reconfigure the processor 440 to use the spare part 434. Note that with the illustrative architecture shown in FIG. 3, the spare part 434 can be physically close to the original defective part (e.g., 432), which would make reconfiguration straightforward and would minimize the impact on performance. In some current systems, the spare part (such as a processor core) is not very likely not to even be on the same chip or even on the same Multi-Chip Module (MCM). Sparing action and reconfiguration in such systems often tends to be quite complicated.

In one embodiment, switching element 436 includes one or more arrays of e-fuses 438, or programmable fuses, which are placed on the additional active layer 404. These e-fuses 438 may be implemented for the activation and reconfiguration of the spare parts 434. The switching elements 436 can also be responsible for activating additional resources (such as an extra core 445) to handle unexpectedly heavy processing loads. Core 445 may be placed on one of the active layers 404 and 406 as well as or in addition to being on base chip 420. The array of e-fuses and/or control logic 438 are preferably in close physical proximity to the monitored units (e.g., processor core 440) to ensure that the latency of sparing action after defect detection is minimal.

Additional area can also be used to achieve higher levels of physical redundancy, which are not provided in two-dimensional semiconductors. While binary redundancy permits the detection of a fault, only tertiary redundancy is capable, using majority voting, for deciding which of two identical units is defective. Current computer systems may only have two cores per chip running concurrently, and hardware errors are detected using comparisons between outputs of the cores. If recovery from a local hardware error fails to occur, both cores are “checkstopped” with an obvious hit on resource availability and a noticeable latency on the restoration of execution. Such a hit will be avoided if three-dimensional chips are employed as the two cores that are in agreement will continue execution. This tertiary scheme assumes that two cores are very unlikely to fail concurrently at the same execution point.

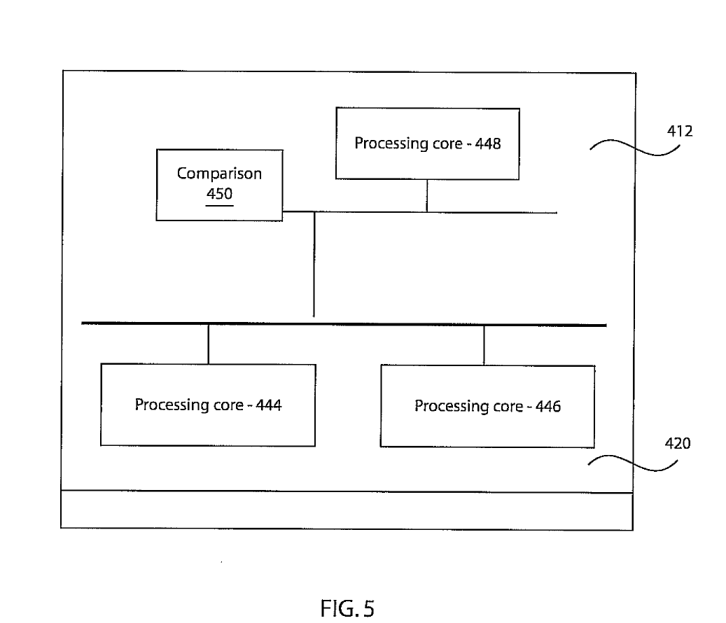

Referring to FIG. 5, a base chip 420 includes two processing cores 444 and 446. One or more additional processing cores 448 are provided on an additional active layer 412. With the addition of processing core 448 (additional processing cores may be added as well) a tertiary redundancy scheme is available. Using majority voting, a decision can be made by a comparison module or device 450 to decide which of the identical units is defective. In a system with three processing cores, two processing cores with the same result will be deemed to be correct and the third defective processing node can be taken off-line. The close physical proximity of the processing cores provides little or no degradation in performance despite the use of a spare processing core. In addition, since each processing core is on a different active layer more heat dissipation measures may be taken to ensure proper operation. Although described in terms of processing cores, other redundant systems or components may be employed.

One form of fault detection and correction, especially for dense memory systems and high-speed communication buses, includes error-correcting codes (ECC). For embedded memory, a method for detecting memory errors includes the Hamming code of double error detection and single error correction. In hardware, the Hamming code is implemented using combinational logic. Latency and area overhead in two-dimensional semiconductors are two reasons that deeper forms of ECC are not used. Such deeper forms (e.g., multi-error corrections) are now needed because of the increasing sensitivity of memory systems (such as on-chip caches) to manufacturing variability and radiation-induced errors. The availability of additional area, in accordance with present principles, enables the implementation of more advanced error correcting schemes.

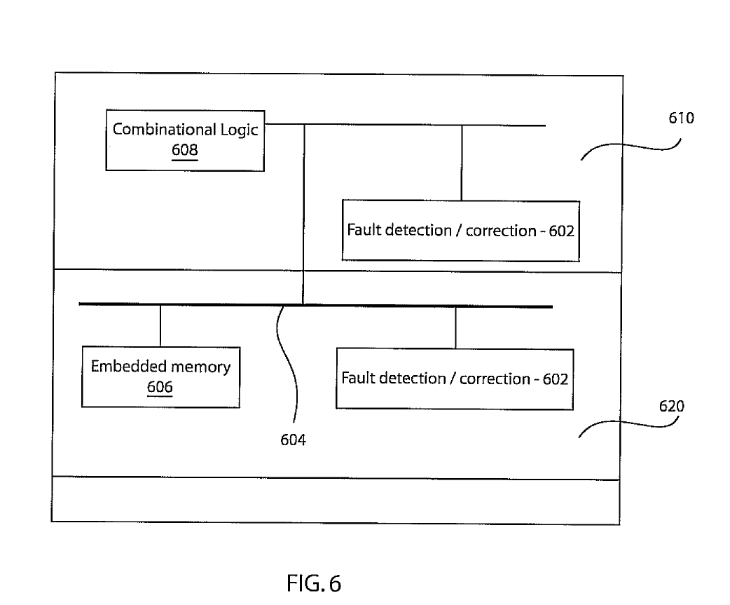

Referring to FIG. 6, a fault detection and correction circuit 602 is implemented for a memory system 600 (with embedded memory 606) with a high-speed communication bus 604, which employs error-correcting codes (ECC). Errors are detected using Hamming code of double error detection and single error correction. The Hamming code is implemented using combinational logic 608. Advantageously, a deeper form of the Hamming code (e.g., multi-error corrections) is enabled to provide a more advanced error correcting schemes by providing a larger area to place circuit 602. Circuit 602 may occupy portion of a base chip 620, active device layer 610 and any other active device layers. The vertical proximity of the portion of circuit 602 can be maintained such that the portions of circuit 602 are closer than had the portion been placed on the base chip 620 in the same substrate area.

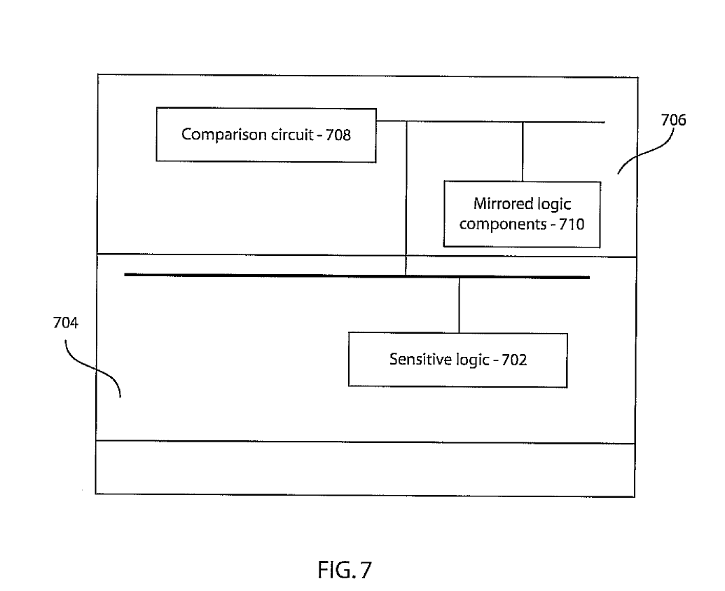

Referring to FIG. 7, logic devices are becoming more sensitive to radiation-induced errors. Three-dimensional chips offer the possibility of having finer-grain monitoring of sensitive logic components so that soft errors can be detected as early as possible. To do so, logic 702 on a base layer 704 that is sensitive to such errors can be mirrored by a (redundant) device 710 on an active layer 706 and comparison circuits 708 may be placed on the active layer 706 to detect errors and activate sparing and reconfiguration actions. Such a fine-grain approach can be contrasted with the coarse, core-based method for detecting hardware errors. In addition, a tertiary, majority vote approach may be employed as described above.

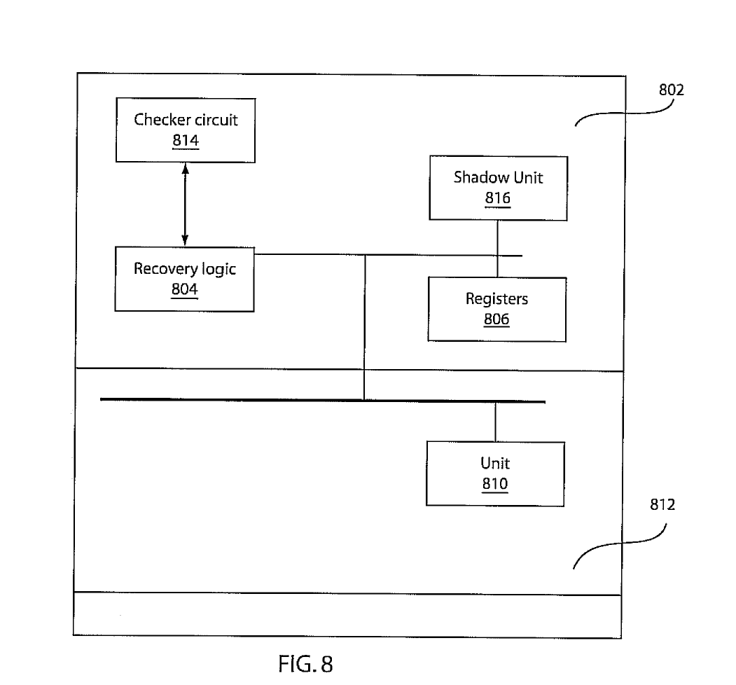

Referring to FIG. 8, an additional active layer 802 may also include control or recovery logic 804 and registers 806 needed to save and fetch states of units 810 on a base layer 812 so as to enable local rollback to a correct state and fast recovery whenever an error is detected. In such situations the recovery logic 804 is activated by a checker circuit 814 based on shadowing of a unit 810 being checked. A shadow unit 816 is located on the additional active layer 802. The shadow unit 816 is slaved to the unit 810, the master, and sees the same inputs. The shadow unit's outputs are solely used for monitoring and do not communicate with off-chip components. Note that the additional substrate area will permit the recovery registers 806 to have significant sizes, thus enabling several states over several clock cycles to be stored and fetched at recovery.

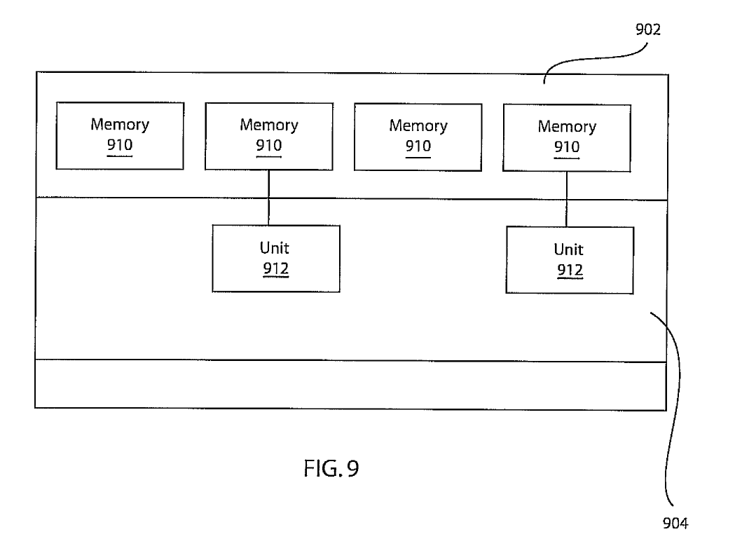

Referring to FIG. 9, an active layer 902 may be employed to provide memory storage devices 910 for units 912 on a base chip 904 (or vice versa). The memory storage may include dynamic random access memory (DRAM), read only memory (ROM), flash memory, registers, or any other memory storage elements or device. Each unit 912 may have its own dedicated memory 910 (e.g., cache) on active layer 902, or the memory 910 may be a bank of cells which may be usable by any device or devices on base chip 904. Units 912 may be processors or processing cores, functional units, error detection/correction devices, etc.

Advantageously, the memory storage 910 may be placed close to the areas of the base chip 904 that need to use the memory. The vertical distance above and below base chip can provide a large amount of memory space in close proximity to the device or unit that needs to use the storage space. This can greatly improve performance due at least to the reduction in delay time for memory accesses of the units 912.

Having described preferred embodiments for three-dimensional architectures for self-checking and self-repairing integrated circuits and methods (which are intended to be illustrative and not limiting), it is noted that modifications and variations can be made by persons skilled in the art in light of the above teachings. It is therefore to be understood that changes may be made in the particular embodiments disclosed which are within the scope and spirit of the invention as outlined by the appended claims. Having thus described aspects of the invention, with the details and particularity required by the patent laws, what is claimed and desired protected by Letters Patent is set forth in the appended claims.

What is claimed is:

1. A three-dimensional architecture chip, comprising:
a base chip including a unit integrated thereon and configured to perform electrical signal operations;
an active layer separately fabricated from the base layer, the active layer including a component to service the unit of the base chip, the active layer being bonded to the base chip such that the component is aligned in vertical proximity of the unit; and
at least one electrical connection connecting the unit to the component through vertical layers of at least one of the base chip and the active layer.

2. The chip as recited in claim 1, further comprising additional active layers having components for providing services to the unit bonded to one of the base chip and the active layer and electrically connected thereto.

3. The chip as recited in claim 1, wherein the unit includes a processing core and the component includes an error detection circuit.

4. The chip as recited in claim 1, wherein the component includes a redundant device capable of replacing the unit.

5. The chip as recited in claim 1, wherein the component includes a plurality of redundant devices capable of detecting errors in the unit by a voting technique.

6. The chip as recited in claim 1, wherein the component includes memory for the unit.

7. The chip as recited in claim 1, wherein the component includes control logic and registers to save and fetch states of the unit to provide recovery and rollback when an error is detected.

8. The chip as recited in claim 1, wherein unit includes a processing core and the component includes a redundant processing core capable of providing additional processing resources to the unit.

9. The chip as recited in claim 1, wherein the component mirrors the unit and receives a same input as the unit, and further comprising a comparison circuit to check an output of the component to detect an error in the integrated unit.

10. A three-dimensional architecture chip, comprising:
a stack of integrated circuit (IC) chips, each IC chip being individually manufactured and assembled into the stack by aligning the IC chips and bonding the chips together;
the stack including:
a first IC chip including an integrated unit configured to perform electrical signal operations;
a second IC chip including a component to service the integrated unit, wherein the first integrated circuit chip and the second integrated circuit chip are configured to permit vertical proximity between the integrated unit and the component, when aligned for bonding; and
at least one electrical connection connecting the integrated unit to the component through vertical layers of at least one of the first IC chip and the second IC chip.

11. The chip as recited in claim 10, further comprising additional IC chips layers having components for providing services to the integrated unit, the additional IC chip being bonded to one of the first IC chip and the second IC chip and electrically connected thereto.

12. The chip as recited in claim 10, wherein the integrated unit includes a processing core and the component includes an error detection circuit.

13. The chip as recited in claim 10, wherein the component includes a redundant device capable of replacing the integrated unit.

14. The chip as recited in claim 10, wherein the component includes a plurality of redundant devices capable of detecting errors in the unit by a voting technique.

15. The chip as recited in claim 10, wherein the component includes memory for the integrated unit.

16. The chip as recited in claim 10, wherein the component includes control logic and registers to save and fetch states of the integrated unit to provide recovery and rollback when an error is detected.

17. The chip as recited in claim 10, wherein the integrated unit includes a processing core and the component includes a redundant processing core capable of providing additional processing resources to the unit.

18. The chip as recited in claim 10, wherein the component mirrors the integrated unit and receives a same input as the integrated unit, and further comprising a comparison circuit to check an output of the component to detect an error in the integrated unit.

19. A method for fabricating a three-dimensional architecture chip, comprising:
constructing a first chip with an integrated unit located at a first position, the integrated unit configured to perform electrical signal operations;
separately constructing an active layer, the active layer including a component to service the unit of the base chip, the component being locating on the active layer at a second position;
aligning the active layer to the first chip such that the integrated unit is vertically proximate to the component;
bonding the active layer to the base chip such that the component is aligned in vertical proximity of the unit; and
forming at least one electrical connection connecting the unit to the component through vertical layers of at least one of the first chip and the active layer.

20. The method as recited in claim 19, wherein the component includes one or a self-checking circuit and self-repair circuit configured to service the integrated unit.
